(19) United States
(12) Patent Application Publication
(10) Pub. No.: US 2012/0097430 A1
(43) Pub. Date: Apr. 26, 2012

(54) PACKAGING SUBSTRATE AND METHOD OF FABRICATING THE SAME

(75) Inventors: Pao-Hung Chou, Taoyuan (TW); Hsien-Min Chang, Taoyuan (TW)

(73) Assignee: UNIMICRON TECHNOLOGY CORPORATION, Taoyuan (TW)

(21) Appl. No.: 13/243,465

(22) Filed: Sep. 23, 2011

(30) Foreign Application Priority Data
Oct. 26, 2010 (TW) 099136609

(51) Int. Cl. H05K 1/02; H05K 3/10

(52) U.S. Cl. 174/251; 29/846

(57) ABSTRACT

A packaging substrate and a method of fabricating the packaging substrate. The packaging substrate includes: a dielectric layer that has an external contact surface and an opposing chip mounting surface; a circuit layer that is embedded in the dielectric layer and exposed from the external contact surface and the chip mounting surface, the circuit layer having wire-bonding pads, conductive pads, and a circuit that electrically connects the wire-bonding pads and the conductive pads, wherein the widths of the wire-bonding pads, conductive pads, and the circuit narrow gradually from chip mounting surface to the external contact surface; and a first insulating protective layer disposed on the external contact surface of the dielectric layer and covering the dielectric layer and the circuit layer, a plurality of conductive pad openings being formed in the first insulating protective layer for exposing the conductive pads. The dielectric layer is used directly as a foundation of the packaging substrate, thereby providing advantage in miniaturization, simpler fabrication procedure, and thus low cost production.

### BACKGROUND OF THE INVENTION

1. Field of the Invention

This invention relates to a packaging substrates and methods of fabricating the same, and, more particularly, to a packaging substrate having a single circuit layer, and a method of fabricating the packaging substrate.

2. Description of Related Art

A lead frame packaging substrate has been long used in a semiconductor chip package, since it has a low cost and high reliability. For a semiconductor chip having a small number of I/Os, the lead frame packaging substrate is still competitive in the cost.

A simple electronic product may need a packaging substrate having a single layer circuit.

Please refer to FIGS. 1A through 1G, which are cross sectional views illustrating a method of fabricating a packaging substrate having a single circuit layer according to the prior art.

As shown in FIG. 1A, a carrier board 10 is provided that has copper layers 11 disposed on both sides thereof.

As shown in FIG. 1B, a resist layer 12 is formed on one of the copper layers 11, and has a plurality of patterned open areas 120 exposing the copper layer 11.

As shown in FIG. 1C, a part of the copper layer 11 that is uncovered by the resist layer 12 is removed, and a circuit layer 111 is formed on the carrier board 10.

As shown in FIG. 1D, the resist layer 12 is removed.

As shown in FIG. 1E, a plurality of through holes 100 that penetrate the carrier board 10 are formed by means of laser, one end of each of the through holes 100 connected to the circuit layer 111.

As shown in FIG. 1F, a first insulating protective layer 13 is disposed on a side of the carrier board 10 having the circuit layer 111. The first insulating protective layer 13 comprises a plurality of first insulating protective layer openings 130 exposing parts of the circuit layer 111. A second insulating protective layer 14 is disposed on the other side of the carrier board 10. The second insulating protective layer 14 comprises a plurality of second insulating protective openings 140 exposing the through holes 100.

As shown in FIG. 1G, a surface treatment layer 15 is disposed on the exposed surface of the circuit layer 111 for solder balls (not shown) to be mounted thereon.

However, the packaging substrate still has the carrier board unremoved that supports the circuit layer. The overall packaging substrate is about 130 μm thick, and is approximately as thick as a general packaging substrate having two layer circuits, which is adverse to the compact-sized and low-profiled requirements.

Hence, how to provide a thinner packaging substrate is becoming one of the most popular issues in the art.

### SUMMARY OF THE INVENTION

In view of the drawbacks of the prior art mentioned above, it is therefore an objective of this invention to provide a thinner packaging substrate and a method of fabricating the same.

To achieve the aforementioned and other objectives, the present invention discloses a packaging substrate, comprising: a dielectric layer having an external contact surface and an opposing chip mounting surface, the dielectric layer being made of epoxy; and a circuit layer embedded in the dielectric layer and exposed from the external contact surface and the chip mounting surface, the circuit layer having wire-bonding pads, conductive pads, and a circuit that electrically connects the wire-bonding pads and the conductive pads, wherein the widths of the wire-bonding pads, the conductive pads, and the circuit narrow gradually from the chip mounting surface to the external contact surface.

In the above-mentioned of the present invention, the packaging substrate further comprises a first insulating protective layer disposed on the external contact surface and covering the circuit layer, the first insulating protective layer having a plurality of conductive pad openings for exposing the conductive pads; and a surface treatment layer disposed on the exposed surface of the circuit layer.

In the above-mentioned of the present invention, the packaging substrate can further comprise a second insulating protective layer disposed on the chip mounting surface and covering the circuit layer, the second insulating protective layer having a plurality of wire-bonding pad openings for exposing the wire-bonding pads; and a surface treatment layer disposed on the exposed surfaces of the wire-bonding pads and the conductive pads.

The present invention further provides a packaging substrate, comprising: a dielectric layer having has an external contact surface and an opposing chip mounting surface; and a circuit layer embedded in the dielectric layer, the circuit layer having wire-bonding pads, conductive pads, and a circuit that electrically connects the wire-bonding pads and the conductive pads, the circuit layer being exposed from the chip mounting surface, the external contact surface of the dielectric layer having a plurality of conductive pad openings for exposing the conductive pads, wherein the widths of the wire-bonding pads, the conductive pads, and the circuit narrow gradually from the chip mounting surface to the external contact surface.

In an embodiment of the present invention, the packaging substrate further comprises an insulating protective layer disposed on the chip mounting surface and covering the circuit layer and the dielectric layer, and a plurality of wire-bonding pad openings formed in the insulating protective layer for exposing the wire-bonding pads; and a surface treatment layer disposed on the exposed surfaces of the wire-bonding pads and the conductive pads.

In another embodiment of the present invention, the packaging substrate further comprises a surface treatment layer disposed on the exposed surface of the circuit layer.

In the above-mentioned of the present invention, the dielectric layer may be made of a solder-resist material or epoxy.

The present invention further discloses a method of fabricating a packaging substrate, comprising: providing a metal board having a first surface and an opposing second surface; removing a part of the metal board from the first surface to form a sunken area and a plurality of metal raised portions preparing for serve as a circuit layer having wire-bonding pads, conductive pads, and a circuit that electrically connects the wire-bonding pads and the conductive pads; forming a dielectric layer on the first surface and the sunken area, the dielectric layer being made of epoxy; removing a partial thickness of the dielectric layer to expose one side of the metal raised portions; and removing a partial thickness of the metal board to expose the other side of the metal raised portions, wherein the dielectric layer with the circuit embedded therein has an external contact surface and an opposing chip mounting surface.

In the above-mentioned of the present invention, the metal raised portions and the sunken area are formed by: forming a resist layer on the first surface, the resist layer having a plurality of patterned open areas exposing the first surface; removing the metal board uncovered by the resist layer to form the metal raised portions and the sunken area; and removing the resist layer.

In the above-mentioned of the present invention, a partial thickness of the dielectric layer is removed by brushing or grinding surface of the dielectric layer such that the dielectric layer is at the same level as the first surface.

In the above-mentioned of the present invention, the method further comprises: forming a first insulating protective layer on the external contact surface to cover the circuit layer and the dielectric layer, and forming a plurality of conductive pad openings in the first insulating protective layer for exposing the conductive pads; and forming a surface treatment layer on the exposed surfaces of the metal raised portions.

In an embodiment of the present invention, the method can further comprise: forming a second insulating protective layer on the chip mounting surface to cover the circuit layer and the dielectric layer, and forming a plurality of wire-bonding pad openings in the second insulating protective layer for exposing the wire-bonding pads; and forming a surface treatment layer on the exposed surfaces of the wire-bonding pads and conductive pads.

The present invention further provides another method of fabricating a packaging substrate, comprising: providing a metal board having a first surface and an opposing second surface; removing a part of the metal board on the first surface to form a sunken area and a plurality of metal raised portions preparing to serve as a circuit layer having wire-bonding pads, conductive pads, and a circuit that electrically connects the wire-bonding pads and the conductive pads; forming a dielectric layer on the first surface and the sunken area; forming a plurality of conductive pad openings to expose the conductive pads; and removing a partial thickness of the metal board to expose the metal raised portions.

In the above-mentioned of the present invention, the metal raised portions and the sunken area are formed by: forming a resist layer on the first surface, the resist layer having a plurality of patterned open areas for exposing the first surface; removing the metal board uncovered by the resist layer, thus forming the metal raised portions and the sunken area; and removing the resist layer.

In an embodiment of the present invention, the method further comprises: forming an insulating protective layer on the second surface to cover the metal raised portions and the dielectric layer, and forming a plurality of wire-bonding pad openings to expose the wire-bonding pads; and forming a surface treatment layer on the exposed surface of the wire-bonding pads and the conductive pads.

In another embodiment of the present invention, the method further comprises: forming a surface treatment layer on the exposed surface of the metal raised portions.

In the above-mentioned of the present invention, the dielectric layer may be made of a solder-resist material or epoxy, and the conductive pad openings may be made by laser ablation or photolithography processes.

In view of the above, the packaging substrate of the present invention comprises a single layer circuit and uses the dielectric layer as base, the dielectric layer is directly integrated with the circuit layer into a single layer, not only shortening the electrical signal transmission path, but also ending up reducing overall thickness greatly, thereby achieving the goal of minimization. The packaging substrate of the present invention has shorter production procedure, and there is no need of a wire formation by electro-plating, thereby taking shorter overall fabrication time, increasing production rate, and reducing production cost.

### BRIEF DESCRIPTION OF DRAWINGS

The invention can be more fully understood by reading the following detailed description of the preferred embodiments, with reference made to the accompanying drawings, wherein:

FIGS. 1A through 1G are cross-sectional views illustrating a method of fabricating a packaging substrate having a single layer circuit according to the prior art;

FIGS. 2A through 2I are cross-sectional views illustrating a method of fabricating a packaging substrate of a first embodiment according to the present invention, wherein FIGS. 2G′ and 2G″ are top views depicting different embodiments of FIG. 2G, FIGS. 2H′ and 2I′ are another embodiments of FIGS. 2H and 2I, respectively, and FIGS. 2I and 2I′ are applications of FIGS. 2H and 2H′, respectively;

FIGS. 3A through 3D are cross-sectional views illustrating a method of fabricating a packaging substrate of a second embodiment according to the present invention, wherein FIG. 3D′ is another embodiment of FIG. 3D; and

FIGS. 4A through 4D are cross-sectional views illustrating a method of fabricating a packaging substrate of a third embodiment according to the present invention, wherein FIG. 4D′ is another embodiment of FIG. 4D.

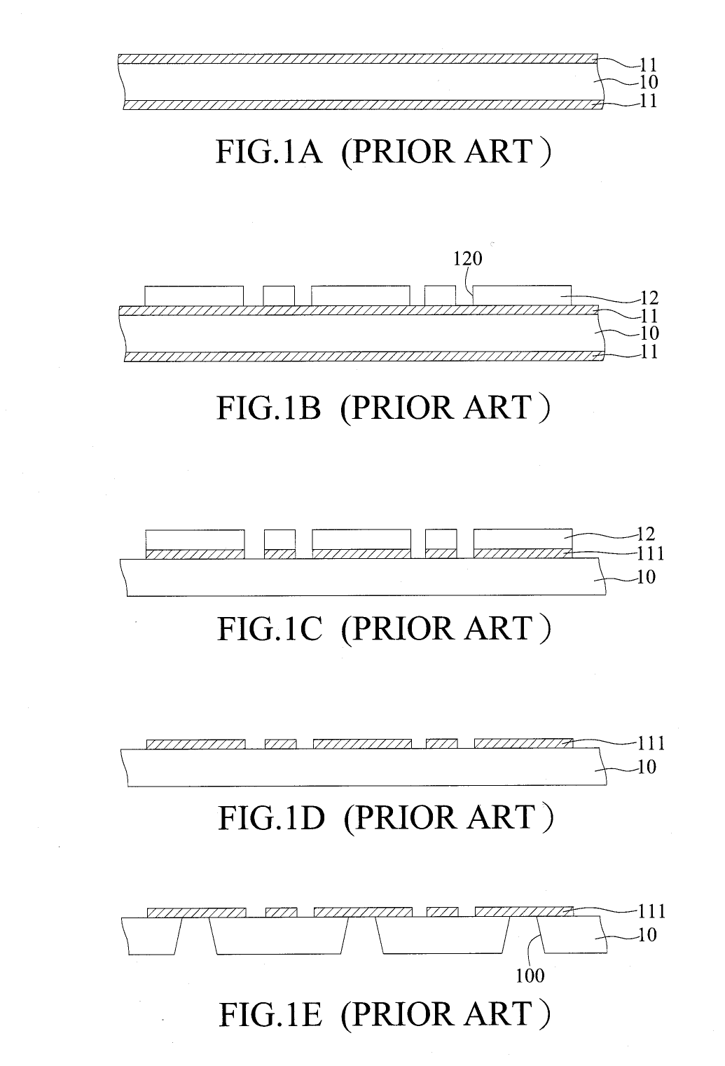

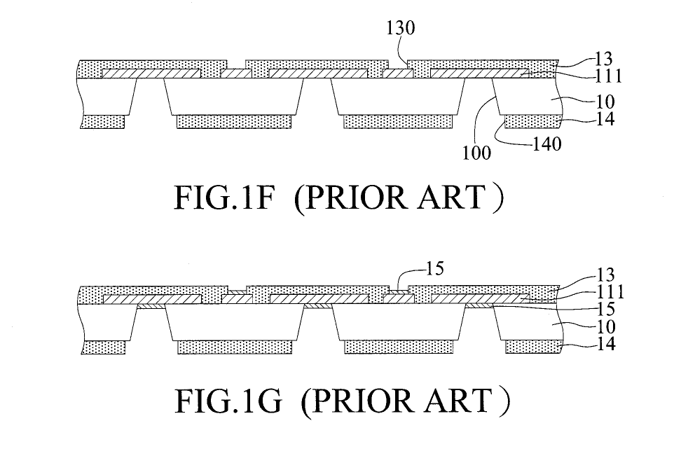

### DETAILED DESCRIPTION OF PREFERRED EMBODIMENTS

The following illustrative embodiments are provided to illustrate the disclosure of the present invention; those in the art can apparently understand these and other advantages and effects after reading the disclosure of this specification. The present invention can also be performed or applied by other different embodiments. The details of the specification may be on the basis of different points and applications, and numerous modifications and variations can be devised without departing from the spirit of the present invention.

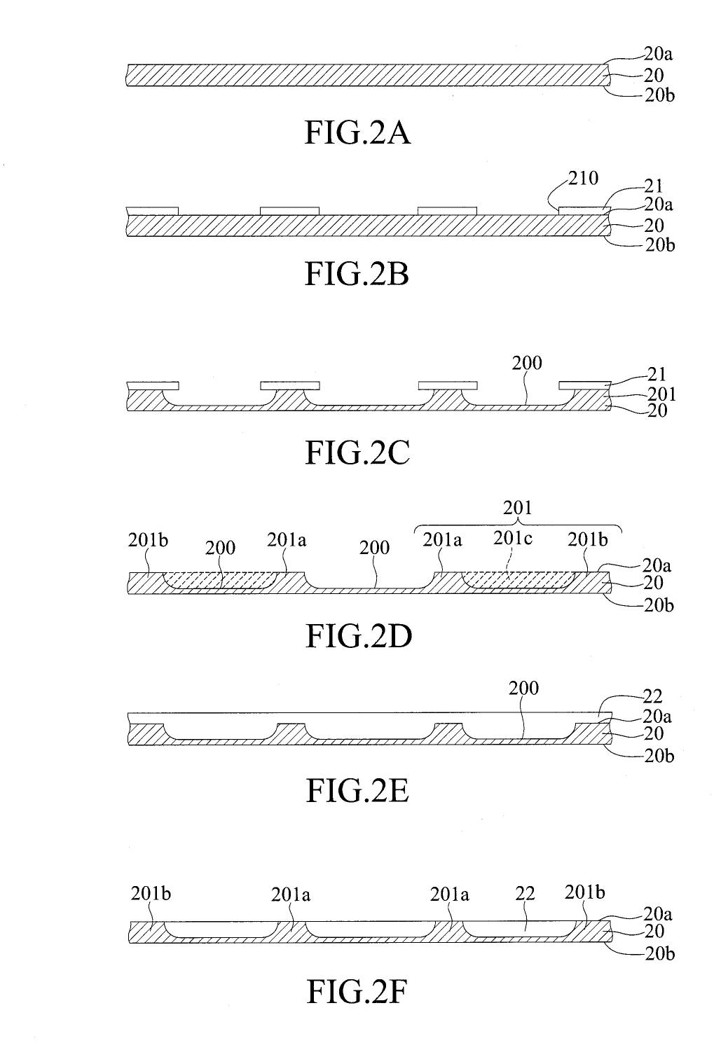

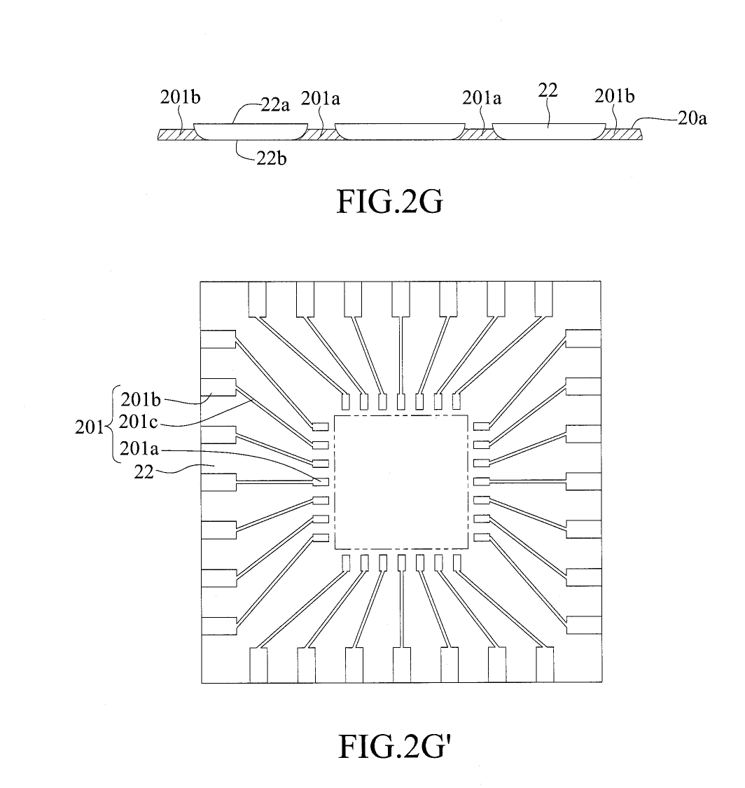

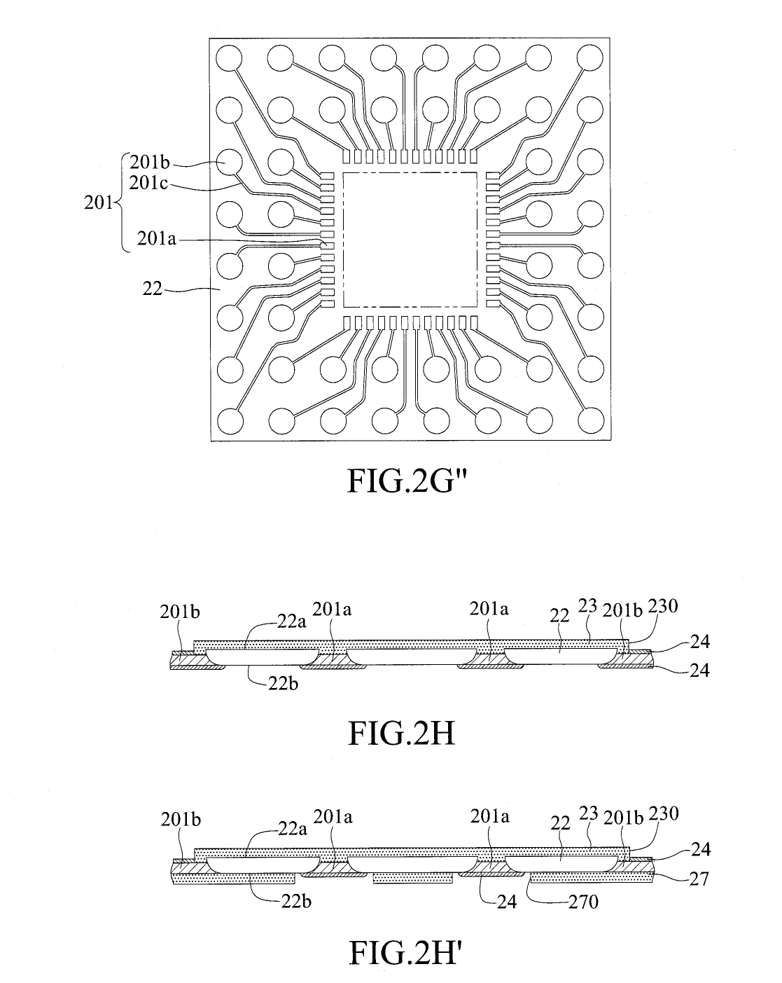

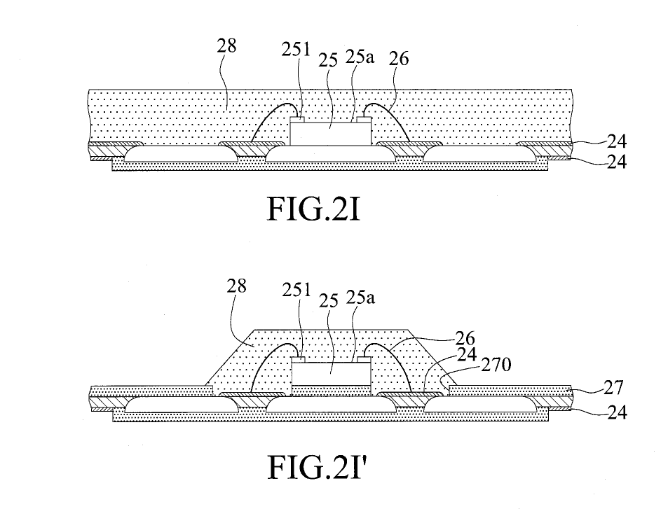

Please refer to FIGS. 2A through 2I, which are cross-sectional views illustrating a method of fabricating a packaging substrate of a first embodiment according to the present invention, wherein FIG. 2G′ and 2G″ are top views depicting different embodiments of FIG. 2G, and FIGS. 2H′ and 2I′ are another embodiments of FIGS. 2H and 2I, respectively.

As shown in FIG. 2A, a metal board 20 is provided that has a first surface 20a and an opposing second surface 20b.

As shown in FIG. 2B, a resist layer 21 is formed on the first surface 20a, the resist layer 21 having a plurality of patterned open areas 210 exposing the first surface 20a.

As shown in FIG. 2C, a portion of the metal board 20 that is uncovered by the resist layer 21 is removed, to form a sunken area 200 and a plurality of metal raised portions 201 preparing to serve as a circuit layer.

As shown in FIG. 2D, the resist layer 21 is removed. The circuit layer, namely the metal raised portions 201, comprises wire-bonding pads 201a, conductive pads 201b, and a circuit 201c that electrically connects the wire-bonding pads 201a and the conductive pads 201b.

As shown in FIG. 2E, a dielectric layer 22 is formed on the first surface 20a and the sunken area 200. The dielectric layer 22 may be made of epoxy.

As shown in the FIG. 2F, a partial thickness of the dielectric layer 22 is removed, to expose one side of the metal raised portions 201. The partial thickness of the dielectric layer 22 may be removed by brushing or grinding a surface of the dielectric layer 22 such that the dielectric layer 22 is at the same level as the first surface 20a.

As shown in FIG. 2G a partial thickness of the metal board 20 is removed, to expose the other side of the metal raised portions 201. The dielectric layer 22 with the circuit layer 22 embedded therein has an external contact surface 22a and an opposing chip mounting surface 22b.

FIGS. 2G′ and 2G″ are top views of different embodiments of FIG. 2G. In the embodiment shown in FIG. 2G′, the conductive pads 201b are solder leg pads applicable to Quad flat No Leads (QFN). In the embodiment shown in FIG. 2G″, the conductive pads 201b are solder ball pads applicable to Ball Grid Arrays.

As shown in FIG. 2H, a first insulating protective layer 23 is formed on the external contact surface 22a to cover the circuit layer and the dielectric layer 22, and a plurality of conductive pad openings 230 are formed in the first insulating protective layer 23 to correspondingly expose the conductive pads 201b. Then, a surface treatment layer 24 is formed on the exposed surface of the metal raised portions 201.

In another embodiment shown in FIG. 2H′, a second insulating protective layer 27 is further formed on the chip mounting surface 22b to cover the circuit layer and the dielectric layer 22, and a plurality of wire-bonding pad openings 270 are formed in the second insulating protective layer 27 to correspondingly expose the wire-bonding pads 201a. Then, a surface treatment layer 24 is formed on the exposed surface of the wire-bonding pads 201a and the conductive pads 201b. In an embodiment of the present invention, the surface processing surface 24 may be made of Ni/Au or Electroless Nickel/Electroless Palladium/Immersion Gold (ENEPIG). In the embodiment shown in FIG. 2H′, the surface treatment layer 24 may be made of an Organic Solderability Preservative (OSP) layer.

As shown in FIGS. 2I and 2I′, which are diagrams depicting applications of FIGS. 2H and 2H′, respectively, a semiconductor chip 25 is mounted on a chip mounting area of the packaging substrate. The semiconductor chip 25 has an active surface 25a that has a plurality of electrode pads 251. The electrode pads 251 are electrically connected to the wire-bonding pads 201a via bonding wires 26. An encapsulation material 28 is also formed to encapsulate the semiconductor chip 25 and the bonding wires 26. A package structure is thus completed.

It should be noted here, after completing the package structure of FIG. 2I or FIG. 2I′, solder balls (not shown) may be further disposed on the surface treatment layer 24, according to a subsequent application situation, for electrically connecting to an external electronic device such as a circuit board.

The present invention further disclose a packaging substrate, comprising: a dielectric layer 22 having has an external contact surface 22a and an opposing chip mounting surface 22b, the dielectric layer 22 made of epoxy, for example; and a circuit layer embedded in the dielectric layer 22 and exposed from the external contact surface 22a and the chip mounting surface 22b, the circuit layer having wire-bonding pads 201a, conductive pads 201b, and a circuit 201c that electrically connects the wire-bonding pads 201a and the conductive pads 201b. The wire-bonding pads 201a, the conductive pads 201b, and the circuit 201c narrow gradually from the chip mounting surface 22b to the external contact surface 22a.

In an embodiment of the present invention, the packaging substrate may further comprise a first insulating protective layer 23 that is disposed on the external contact surface 22a and covers the circuit layer. The first insulating protective layer 23 may comprise a plurality of conductive pad openings for exposing the conductive pads 201b. A surface treatment layer 24 may be further disposed on the exposed surface of the circuit layer.

In an embodiment of the present invention, the packaging substrate may further comprise a second insulating protective layer 27 that is disposed on the chip mounting surface 22b and covers the circuit layer. The second insulating protective layer 27 may comprise a plurality of wire-bonding pad openings 270 for exposing the wire-bonding pads 201a. A surface treatment layer 24 may be further disposed on the exposed surfaces of the wire-bonding pads and the conductive pads.

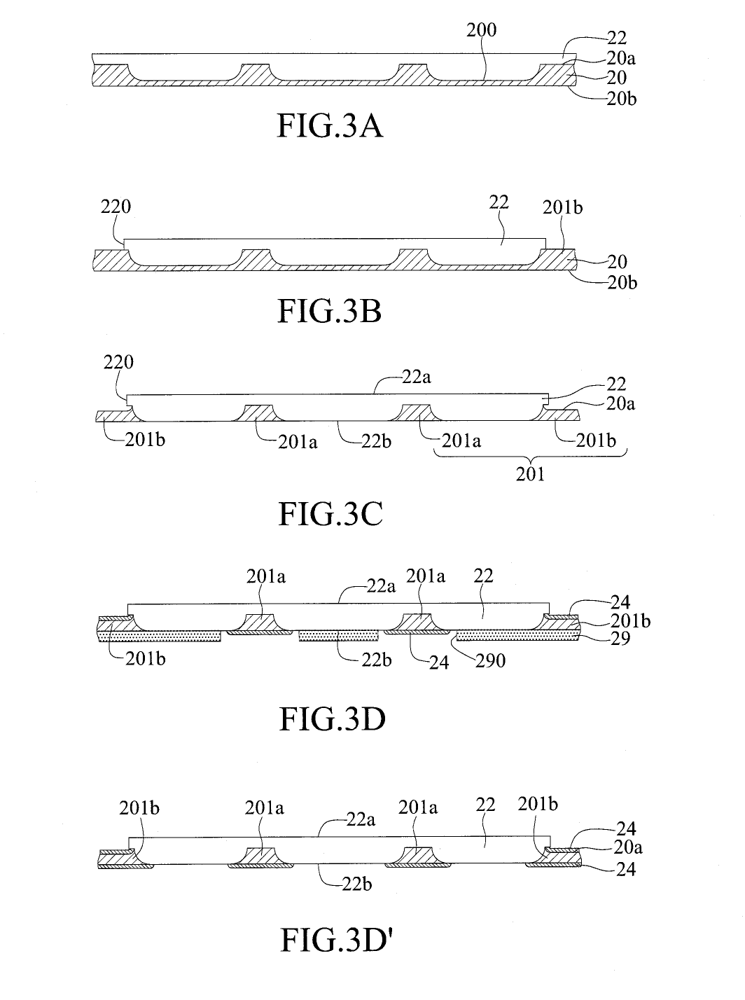

Please refer to FIGS. 3A through 3D, which are cross-sectional views illustrating a method of fabricating a packaging substrate of a second embodiment according to the present invention, wherein FIG. 3D′ is another embodiment of FIG. 3D.

As shown in FIG. 3A, which is derived from FIG. 2D, a dielectric layer 22 is formed on the first surface 20a and the sunken area 200. In an embodiment of the present invention, the dielectric layer 22 is made of epoxy.

As shown in FIG. 3B, a plurality of conductive pad openings 220 are formed in the dielectric layer 22 to expose the conductive pads 201b. In an embodiment of the present invention, the conductive pad openings 220 may be formed by laser ablation or photolithography processes.

As shown in FIG. 3C, a partial thickness of the metal board 20 is removed to expose the metal raised portions 201.

As shown in FIG. 3D, an insulating protective layer 29 is formed on the second surface 20b to cover the metal raised portions 201 and the dielectric layer 22, and a plurality of wire-bonding pad openings 290 are formed in the insulating protective layer 29 for exposing the wire-bonding pads 201a. Then, a surface treatment layer 24 is formed on the exposed surfaces of the metal raised portions 201.

In another embodiment shown in FIG. 3D′, instead of the insulating protective layer 29, a surface treatment layer 24 is formed on the exposed surfaces of the metal raised portions 201. The surface treatment layer 24 may be made of Ni/Au or Electroless Nickel/Electroless Palladium/Immersion Gold (ENEPIG).

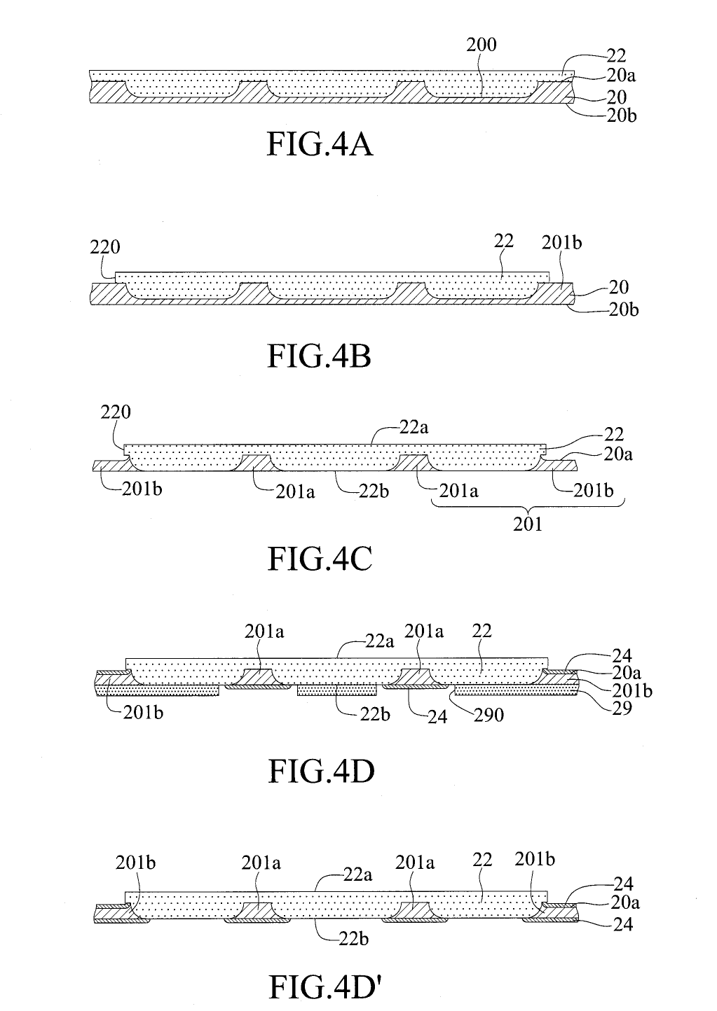

Please refer to FIGS. 4A through 4D, which are cross-sectional views illustrating a method of fabricating a packaging substrate of a third embodiment according to the present invention, wherein FIG. 4D′ is another embodiment of FIG. 4D.

The third embodiment is different from the second embodiment in that the dielectric layer 22 is made of solder-resist material in the third embodiment, while epoxy in the second embodiment.

The present invention further discloses another packaging substrate, comprising: a dielectric layer 22 having an external contact surface 22a and an opposing chip mounting surface 22b; and a circuit layer embedded in the dielectric layer 22 and having wire-bonding pads 201a, conductive pads 201b, and circuit 201c that electrically connects the wire-bonding pads 201a and the conductive pads 201b. The circuit layer is exposed from the chip mounting surface 22b, and the external contact surface 22a of the dielectric layer 22 has a plurality of conductive pad openings 220 for exposing the conductive pads 201b. The wire-bonding pads 201a, the conductive pads 201b, and the circuit 201c narrow gradually from the chip mounting surface 22b to the external contact surface 22a.

In an embodiment of the present invention, the packaging substrate may further comprise an insulating protective layer 29 that is disposed on the chip mounting surface 22b and covers the circuit layer and the dielectric layer 22. A plurality of wire-bonding pad openings 290 may be further formed in the insulating protective layer 29 for exposing the wire-bonding pads 201a. A surface treatment layer 24 may be further disposed on the exposed surfaces of the wire-bonding pads 201a and the conductive pads 201b.

In an embodiment of the present invention, the packaging substrate may further comprise a surface treatment layer 24 disposed on the exposed surface of the circuit layer.

In an embodiment of the present invention, the dielectric layer 22 may be made of a solder-resist material or epoxy.

In view of the above, unlike the prior art, the packaging substrate of the present invention comprises a single layer circuit and uses the dielectric layer as base. The dielectric layer is directly integrated with the circuit layer into a single layer, which not only shortens the electrical signal transmission path, but also ends up reducing overall thickness greatly, thereby achieving the goal of minimization. The packaging substrate of the present invention has a simpler production procedure, and there is no need of a wire formation by electro-plating, thereby taking shorter overall fabrication time, increasing production rate, and reducing production cost.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A packaging substrate, which comprises:
a dielectric layer having an external contact surface and an opposing chip mounting surface; and
a circuit layer embedded in the dielectric layer and exposed from the external contact surface and the chip mounting surface, the circuit layer having wire-bonding pads, conductive pads, and a circuit that electrically connects the wire-bonding pads and the conductive pads, wherein the widths of the wire-bonding pads, the conductive pads, and the circuit narrow gradually from the chip mounting surface to the external contact surface.

2. The packaging substrate of claim 1, further comprising a first insulating protective layer disposed on the external contact surface of the dielectric layer and covering the circuit layer, the first insulating protective layer having a plurality of conductive pad openings for exposing the conductive pads.

3. The packaging substrate of claim 2, further comprising a second insulating protective layer disposed the chip mounting surface of the dielectric layer and covering the circuit layer, the second insulating protective layer having a plurality of wire-bonding pad openings for exposing the wire-bonding pads.

4. The packaging substrate of claim 3, wherein further comprising a surface treatment layer, which is disposed on the exposed surface of the wire-bonding pads and the conductive pads.

5. The packaging substrate of claim 2, further comprising a surface treatment layer disposed on the exposed surface of the circuit layer.

6. The packaging substrate of claim 1, wherein the dielectric layer is made of epoxy.

7. A packaging substrate, which comprises:
a dielectric layer having an external contact surface and an opposing chip mounting surface; and
a circuit layer embedded in the dielectric layer and exposed from the chip mounting surface, the circuit layer having wire-bonding pads, conductive pads, and a circuit that electrically connects the wire-bonding pads and the conductive pads, the external contact surface of the dielectric layer having a plurality of conductive pad openings for exposing the conductive pads, wherein the widths of the wire-bonding pads, the conductive pads, and the circuit narrow gradually from the chip mounting surface to the external contact surface.

8. The packaging substrate of claim 7, further comprising an insulating protective layer disposed on the chip mounting surface and covering the circuit layer and the dielectric layer, and a plurality of wire-bonding pad openings formed in the insulating protective layer for exposing the wire-bonding pads.

9. The packaging substrate of claim 8, further comprising a surface treatment layer disposed on the exposed surface of the wire-bonding pads and the conductive pads.

10. The packaging substrate of claim 7, further comprising a surface treatment layer disposed on the exposed surface of the circuit layer.

11. The packaging substrate of claim 7, wherein the dielectric layer is made of a solder-resist material or epoxy.

12. A method of fabricating a packaging substrate, comprising:
providing a metal board having a first surface and an opposing second surface;
removing a partial thickness of the metal board from the first surface to form a sunken area and a plurality of metal raised portions preparing to serve as a circuit layer having wire-bonding pads, conductive pads, and a circuit electrically connecting the wire-bonding pads and the conductive pads;
forming a dielectric layer on the first surface and the sunken area;
removing a partial thickness of the dielectric layer to expose one side of the metal raised portions; and
removing a partial thickness of the metal board to expose the other side of the metal raised portions, wherein the dielectric layer with the circuit layer embedded therein has an external contact surface and an opposing chip mounting surface.

13. The method of claim 12, wherein the metal raised portions and the sunken area are made by:
forming a resist layer on the first surface, the resist layer having a plurality of patterned open areas for exposing the first surface;
removing a part of the metal board uncovered by the resist layer, thereby forming the metal raised portions and the sunken area; and
removing the resist layer.

14. The method of claim 12, wherein the partial thickness of the dielectric layer is removed by brushing or grinding surface of the dielectric layer such that the dielectric layer is at the same level as the first surface.

15. The method of claim 12, further comprising forming a first insulating protective layer on the external contact surface to cover the circuit layer and the dielectric layer, and forming a plurality of conductive pad openings for exposing the conductive pads.

16. The method of claim 15, further comprising forming a second insulating protective layer on the chip mounting surface to cover the circuit layer and the dielectric layer, and forming a plurality of wire-bonding pad openings for exposing of the wire-bonding pads.

17. The method of claim 12, wherein the dielectric layer is made of epoxy.

18. A method of fabricating a packaging substrate, comprising:
providing a metal board having a first surface and an opposing second surface;
removing a part of the metal board on the first surface to form a sunken area and a plurality of metal raised portions that prepare to serve as a circuit layer comprising wire-bonding pads, conductive pads, and a circuit that electrically connects the wire-bonding pads and conductive pads;
forming a dielectric layer on the first surface and the sunken area;
forming a plurality of conductive pad openings in the dielectric layer for exposing of the conductive pads; and
removing a partial thickness of the metal board to expose the metal raised portions.

19. The method of claim 18, wherein the metal raised portions and the sunken area are made by:
forming a resist layer on the first surface, the resist layer having a plurality of patterned open areas that expose the first surface;
removing the metal board uncovered by the resist layer, thereby forming the metal raised portions and the sunken area; and
removing the resist layer.

20. The method of packaging substrate of claim 18, further comprising forming an insulating protective layer on the second surface to cover the metal raised portions and the dielectric layer, and forming a plurality of wire-bonding pad openings for exposing the wire-bonding pads.

21. The method of claim 18, wherein the conductive pad openings are formed by means of laser ablation or photolithography.

22. The method of claim 18, wherein the dielectric layer is made of a solder-resist material or epoxy.
